(19) United States
(12) Patent Application Publication
(10) Pub. No.: US 2026/0319017 A1
(43) Pub. Date: Oct. 15, 2026

(54) CONTROLLER FOR A CHARGING DEVICE FOR A VEHICLE, CHARGING DEVICE AND METHOD FOR OPERATING THE CONTROLLER

(71) Applicant: Robert Bosch GmbH, Stuttgart (DE)

(72) Inventor: Koji Jaeger, Kanagawa (JP)

(21) Appl. No.: 19/166,097

(22) PCT Filed: Jan. 23, 2024
(86) PCT No.: PCT/EP2024/051490

§ 371 Date: Sep. 17, 2025

(30) Foreign Application Priority Data
Mar. 17, 2023 (DE) 10 2023 106 693.5

(51) Int. Cl. G01R 31/40; B60L 1/00; B60L 53/16; B60L 53/60

(52) U.S. Cl. CPC G01R 31/40; B60L 1/006; B60L 53/16; B60L 53/60

(57) ABSTRACT

The invention relates to a controller (150) for a charging device (100) for a vehicle (500) and to a V2L device (300), wherein the controller (150) and the V2L device (300) are connected to a protective conductor (510) of the vehicle 500. The controller (150) comprises a diagnostic device (200), which diagnoses a fault in the connection of the V2L device 300 to the protective conductor 510.

### BACKGROUND

The invention relates to a controller for a charging device for a vehicle, a charging device, and a vehicle to load device (V2L device). Further, the invention relates to an energy management system, a vehicle, a method for operating the controller, a computer program, and a computer readable storage medium.

Charging devices, for example in vehicles with an electric drive in an electric vehicle or a hybrid vehicle, are used to recharge batteries, preferably accumulators or traction batteries, from an electrical energy source, preferably from an external alternating voltage source or from the public alternating voltage power supply. During the charging process, electrical energy may be provided in a vehicle having a vehicle to load outlet (V2L socket) for consumers. Consumers connected to the outlet are powered. A controller controls the charging process and the supply of electrical energy to the consumer. During the charging process, this electrical system is considered a grounded electrical system because the external AC power source is grounded via a ground connector. To ensure operational safety, the connection of the V2L device to the ground connector is monitored during charging. Therefore, there is a need for a simple and compact solution for a controller for a charging device that monitors the connection of the V2L device to the ground connector.

### SUMMARY

A controller for a charging device for a vehicle is provided. The controller comprises a diagnostic device. The controller is connectable to a vehicle to load device (V2L device) of the vehicle via a first connection line, preferably an electrical connection line. The controller comprises a first protective conductor connector for connecting to a protective conductor of the vehicle. Preferably, a connectable V2L device comprises a second protective conductor connector for connection to the protective conductor of the vehicle. According to the invention, the diagnostic device comprises a first diagnostic connector for connection to the first connection line and a voltage measuring device configured to determine a voltage between the first diagnostic connector and the first protective conductor connector. The diagnostic device detects or diagnoses a fault and outputs a signal if the determined voltage is less than a predetermined lower threshold value or the determined voltage is greater than a predetermined upper threshold value. Preferably, the diagnostic device detects a faulty electrical connection of the V2L device to the protective conductor of the vehicle. Preferably, an incorrect electrical connection is present if there is no electrical connection of the V2L device to the protective conductor of the vehicle.

The controller is configured for a vehicle having a charging device and a V2L device. A protective conductor is provided in the vehicle, which is connected or connected during a charging operation via a grounding connector, preferably to a grounding cable, of an external charging device, for example a charging station. As the controller and the V2L device are arranged at different locations within the vehicle, both the controller via a first protective conductor connection and preferably the V2L device via a second protective conductor connector are connected to the protective conductor of the vehicle. To ensure that an additional controller for the V2L device is not required, the controller comprises a diagnostic device for diagnosing a faulty connection or connection of the V2L device to the protective conductor of the vehicle. For this purpose, the diagnostic device can be connected to the V2L device via a first diagnostic port with a first connection line. Further, the diagnostic device comprises a voltage measuring device that determines a voltage between the first diagnostic connector and the first protective conductor connector. Depending on the determined voltage, the diagnostic device detects or diagnoses a faulty connection of the V2L device to the protective conductor Advantageously, a simple solution for a controller for a charging device is provided, which monitors the connection of the V2L device to the protective conductor or the ground connector by means of a specifically designed diagnostic device. Preferably, a voltage at the end of the protective conductor is monitored by means of a voltage difference, which can preferably be specified, across the parallel connection line between the end of the protective conductor and a reference point present in the diagnostic device. Preferably, a voltage on the protective conductor within the V2L device is monitored by means of a voltage difference, which can preferably be specified, across the parallel connecting line between the V2L device and the diagnostic device at the diagnostic connector of the diagnostic device.

In one embodiment, the diagnostic device comprises a current source and or voltage source connected on the one hand to the first protective conductor connector and to a first resistor on the other hand, wherein the first resistor is connected between the voltage source and the first diagnostic connector. Preferably, the current source and/or voltage source is configured to provide a specifiable voltage at a first resistor.

By means of the current source and or voltage source, a first resistor impinges a current on the first connection line between the diagnostic connector and the V2L device or a voltage is applied across the first resistor. This adjusts a voltage, which can be specified by means of the current source and or voltage source, between the first connection line and the protective conductor of the vehicle.

Advantageously, a circuit for the diagnostic device is provided, which allows monitoring of the connection of the V2L device and a protective conductor.

In one embodiment, the first resistor is arranged within the controller or within the charging device or within the V2L device. The spatial proximity to the diagnostic device speaks for an arrangement within the controller, so that preferably the first resistor is arranged on the same circuit board with the electronics of the controller and a connection to the diagnostic device is carried out by means of traces. Preferably, no additional cable lines are required to connect the first resistor. Alternatively, the first resistor is preferably arranged elsewhere within the charging device or within the V2L device, optionally combined with electrical connection via additional cables between the current source and or voltage source, the first resistor and the first diagnostic connector.

Advantageously, several possibilities for an arrangement of the first resistor are provided.

In another embodiment of the invention, the charging device comprises a charging connector for connecting an external power source. Preferably, the charging device further comprises a battery connector for connecting a traction battery of the vehicle. When the external power source is connected to the charging device, the protective conductor of the vehicle is connected to a ground cable of the external power source. The ground cable of the external power source is an electrically conductive connection to a ground of the external power source or a PE conductor or a protective conductor of the external power source. Preferably, during operation of the charging device, electrical energy is transferred between at least one of the power sources, the external power source, and/or the traction battery, and at least one of the power sinks, the traction battery, or the V2L device.

During operation of the charging device, in which power is transferred from an external power source into the vehicle, preferably into the traction battery or to supply power to the V2L device, the protective conductor of the vehicle is connected to a ground cable or conductor of the external power source.

Advantageously, this provides a protective measure, namely a protective ground of the controller, the charging device and the vehicle, so that the protective ground serves to keep this touchable part at earth potential in the event of a short circuit between an active, preferably live conductor and a conductive, touchable part, preferably a housing part of the charging device or the vehicle, to keep this touchable part at earth potential and thus prevent or at least reduce the flow of current through the body, preferably a human body, to earth.

The invention also relates to a charging device with a control unit. Preferably, the controller is arranged within the charging device or the controller is connected to the charging device via further connection lines.

A charging device with a controller is advantageously provided.

Further, the invention relates to a V2L device for a vehicle. Preferably, a V2L device is a device that allows electrical power to be supplied from a vehicle, preferably via a socket, which can be used for the operation of consumers. The V2L device comprises a test circuit. The V2L device is connectable to a controller for a charging device of the vehicle via a, preferably electrical, first connection line. The V2L device comprises a second protective conductor connector for connection to a protective conductor of the vehicle. Preferably, the controller comprises a first protective conductor connection for connection to the protective conductor of the vehicle. The test circuit comprises a first test connector for connection to the first connection line. Further, the V2L device comprises a second resistor. Preferably, a series circuit consisting of a first resistor and the second resistor forms a voltage divider. The second resistor is connected between the first test connector and the second protective conductor connector.

A V2L device with a test circuit is provided. The test circuit comprises a second resistor, a first test connector, and a second protective conductor connector. The second resistor is connected between the first test connector and the second protective conductor connector.

Advantageously, a V2L device is provided that comprises a test circuit that allows the connection of the V2L device to the protective conductor or ground connector to be monitored by means of a specifically configured diagnostic device.

In one embodiment, the test circuit comprises a first resistor and a second test connector. A series circuit of the first resistor and the second resistor form a voltage divider. The first resistor is connected to the second test connector on the one hand, and is connected to the second resistor via an intermediate tap on the other hand. The second resistor is connected to the second protective conductor connector on the one hand, and connected to the first resistor via the intermediate tap on the other hand. The intermediate tap is connected to the first test connector.

Preferably, during operation of the V2L device, the second test connector is connected to a second diagnostic connector of the controller, wherein the first test connector is connected to the first diagnostic connector of the controller.

A V2L device with a test circuit is provided. The test circuit comprises a first and a second resistor, a first and a second test connector, and a second protective conductor connector. The second resistor is connected between the first test connector and the second protective conductor connector.

Advantageously, an alternative V2L device is provided that comprises a test circuit that allows the connection of the V2L device to the protective conductor or ground connector to be monitored by means of a specifically configured diagnostic device.

In one embodiment, the V2L device comprises a socket for connecting a, preferably mobile, consumer. The socket includes a protective connector connected to the second protective conductor connector. Preferably, when a consumer is connected, the protective conductor of the vehicle is connected via the protective connector to a protective cable of the consumer.

The V2L device comprises a socket for connecting a consumer. Preferably, these are mobile or commercially available consumers for operation at a socket of the electrical power system in a home, in an apartment, in a backyard or in a workshop. Such consumers may be electrical appliances or consumers used for food preparation, for example a coffee maker or a grill, or domestic appliances such as a vacuum cleaner or tools such as a compressor or a saw.

These devices comprise a protective cable, which is connected to the protective conductor of the vehicle via the protective connector of the V2L device's socket.

Advantageously, a V2L device is provided with a socket, whose protective connector is connected to the protective conductor of the vehicle, wherein by means of a specifically configured diagnostic device, monitoring of the connection of the V2L device to the protective conductor of the vehicle or the ground connection is enabled.

Further, the invention relates to an energy management system for a vehicle. The energy management system comprises a controller or a charging device having a controller and a V2L device. The first diagnostic connector is connected to the first test connector of the V2L device via a first connection line. Preferably, a second diagnostic connector is connected to a second test connector of the V2L device via a second connection line.

Advantageously, an energy management system consisting of a controller and a connected V2L device is provided, which allows monitoring of the connection of the V2L device to the protective conductor of the vehicle or the ground connection.

Further, the invention relates to a vehicle having a controller and a V2L device or an energy management system.

Advantageously, a vehicle comprising a controller with a connected V2L device is provided, which allows monitoring of the connection of the V2L device to the protective conductor of the vehicle or the ground connector.

The invention further relates to a method for operating a controller with the steps of: determining a voltage between a first diagnostic connector and a first protective conductor connector and outputting a signal if the determined voltage is less than a predetermined lower threshold value or greater than a predetermined upper threshold value.

By means of determining the voltage between the first diagnostic connector and the first protective conductor connector, it can be detected whether the protective conductor is connected to the V2L device or not. Preferably, it is detected whether or not the first protective conductor connector of the controller is connected to the second protective conductor connector of the V2L device via the protective conductor of the vehicle. It is preferably detected whether there is a continuous connection of the protective conductor between the V2L device and the diagnostic circuit. Preferably, the upper and lower threshold values result from the sizing of the first and second resistors and the applied voltage or current of the current source and or voltage source. If the determined voltage is less than a lower threshold value, there is a fault in the diagnostic circuit, preferably the current source and or voltage source. If the determined voltage is greater than an upper threshold value, the connection of the V2L device to the protective conductor is interrupted. Preferably, the connection between the first protective conductor connector of the controller and the second protective conductor connector of the V2L device via the protective conductor of the vehicle is interrupted if the determined voltage is greater than an upper threshold value. Preferably, at least two different types of failure are diagnosed. Preferably, depending on the type of error, a specific signal is output, preferably a first signal for a detected error of a first type of error and a second signal for a detected error of a second type of error.

Advantageously, there is provided a method by which connection of a V2L socket or the V2L device to the protective conductor or ground connector is monitored.

The invention further relates to a computer program comprising commands which, when the program is executed by a controller, cause it to carry out the method.

The invention also relates to a computer-readable storage medium comprising commands which, when executed by a control unit, cause it to carry out the method.

It is understood that the features, properties, and advantages of the charging device apply or can be applied accordingly to the method or the drive train and the vehicle and vice versa.

Further features and advantages of embodiments of the invention are apparent from the following description with reference to the accompanying drawings.

### BRIEF DESCRIPTION OF THE DRAWINGS

The invention will be explained in further detail hereinafter with reference to the drawings:

FIG. 1 a schematic illustration of a vehicle having a controller and a V2L device FIG. 2 an alternative schematic illustration of a vehicle having a controller and a V2L device

FIG. 3 a schematic illustration of a flow chart for a method for operating a charging device

### DETAILED DESCRIPTION

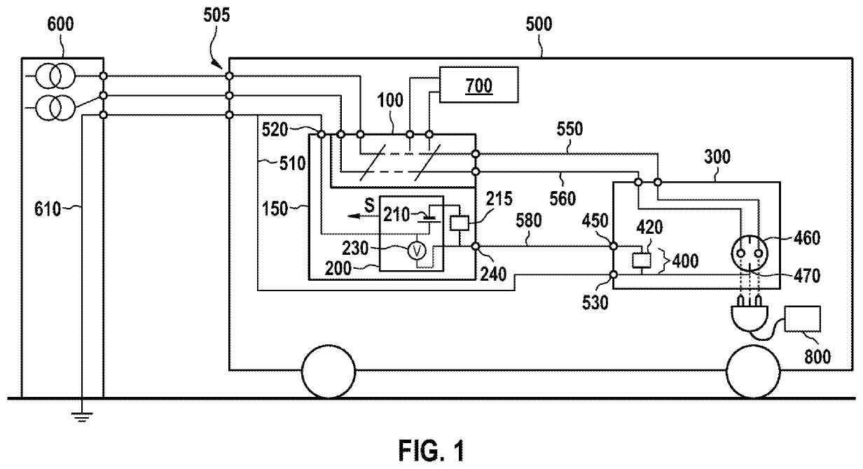

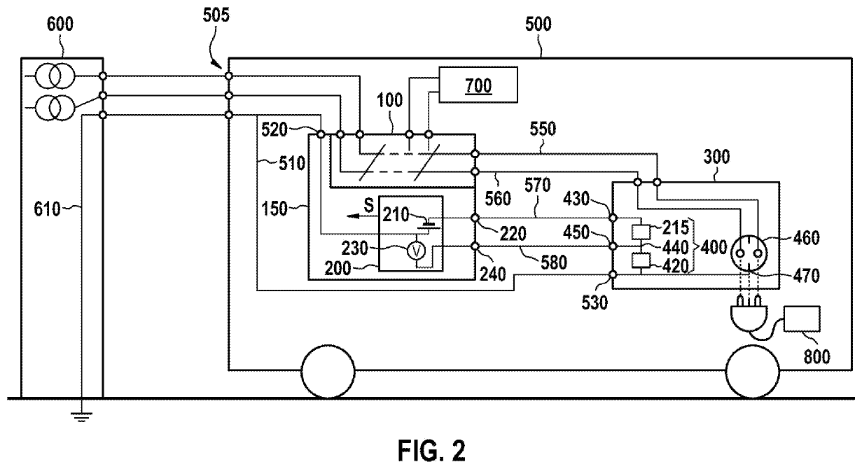

FIG. 1 shows a vehicle 500 and an external power source 600. Preferably, the vehicle 500 is any vehicle for use in the water, on land, or in the air. Preferably, the external power source 600 is, for example, a wallbox in a garage or a stationary charging station of a central or decentralized charging station or a grid connection. Preferably, the external power source 600 is an alternating voltage source or a DC voltage source of one or more phases. The external power source 600 comprises a ground cable 610. Preferably, the ground cable is an electrical cable, a protective conductor, or a PE conductor connected to the potential of the ground. When the external power source 600 is connected to the vehicle 500 via a charging connector 505, a protective conductor 510 of the vehicle is connected to the grounding connector 610 of the external power source 600. The vehicle 500 comprises a charging device 100 that converts electrical power from the external power source 600 to, for example, a DC voltage and or AC voltage. With the converted power, for example in the form of a high-voltage DC voltage, preferably a battery in the vehicle 500, preferably a traction battery 700, or a high-voltage battery, is recharged. Preferably, a traction battery 700 is used to supply an electric drive of the vehicle 500. Preferably, the converted power, for example in the form of an alternating voltage, is supplied to a V2L device 300 via a third and fourth connection line 550, 560, preferably the socket 460 of the V2L device 300, in the vehicle 500. Preferably, a controller 150 controls the operation of the charging device. The controller 150 comprises a diagnostic device 200. The controller 150 is connectable to the V2L device 300 of the vehicle 500 via a first connection line 580. Further, the controller 150 comprises a first protective conductor connector 520 for connection to the protective conductor 510 of the vehicle 500. The V2L device 300 comprises a second protective conductor connector 530 for connection to the protective conductor 510 of the vehicle 500. The diagnostic device 200 comprises a first diagnostic connector 240 for connection to the first connection line 580 and a voltage measuring device 230 configured to determine a voltage between the first diagnostic connector 240 and the first protective conductor connector 520. The diagnostic device 200 diagnoses a fault and outputs a signal S if the determined voltage is less than a predetermined lower threshold value or the determined voltage is greater than a predetermined upper threshold value. Preferably, the diagnostic device 200 comprises a current source and or voltage source 210 connected to the first grounding conductor connector 520 on the one hand and to a first resistor 215 on the other hand. Preferably, the first resistor 215 is connected between the current source and or voltage source 210 and the first diagnostic connector 240. Preferably, the current source and/or voltage source 210 is configured to provide a pre-determinable voltage to the first resistor 215. The V2L device 300 comprises a test circuit 400. The V2L device 300 is preferably connectable to the controller 150 for a charging device 100 of the vehicle 500 via the first connection line 580. The V 2L device 300 comprises a second protective conductor connector 530 for connection to a protective conductor 510 of the vehicle 500. The controller 150 comprises a first ground conductor connector 520 for connection to the ground conductor 510 of the vehicle 500. The test circuit 400 comprises a first test connector 450 for connection to the first connection line 580 and a second resistor 420. The second resistor 420 is connected between the first test connector 450 and the second protective conductor connector 530. The V2L device preferably comprises a socket 460 for connecting a consumer 800. The socket 460 comprises a protective connector 470. The protective connector 470 is connected to the second protective conductor connector 530. When connecting a, preferably mobile, consumer 800, the protective conductor 510 of the vehicle 500 is connected to a protective cable of the consumer 800.

Bases on the vehicle 500 according to FIG. 1, the diagnostic device 200 according to FIG. 2 only comprises the current source and/or voltage source 210 and a first diagnostic connector 240 for connection to the first connection line 580, a second diagnostic connector 220 for connection to a second connection line 570 and a voltage measuring device 230, which is set up determine a voltage between the first diagnostic connector 240 and the first protective conductor connector 520. Accordingly, the test circuit 400 of the V2L device 300 of FIG. 2 comprises a first resistor 215 and a second test connector 430. The test circuit 400 of the V2L device 300 of FIG. 2 comprises a series circuit of the first resistor 215 and the second 420 resistor forming a voltage divider. The first resistor 215 is connected to the second test connector 430 on the one hand, and to the second resistor 420 via an intermediate tap 440 on the other hand. The second resistor 420 is connected to the second protective conductor connector 530 on the one hand, and to the first resistor 215 via the intermediate tap 440 on the other hand. The intermediate tap 440 is connected to the first test connector 450. During operation of the V2L device, the second test connector 430 is connected to the second diagnostic connector 220 of the controller 150 via the second connection line 570. The first test connector 450 is connected to the first diagnostic connector 240 of the controller 150.

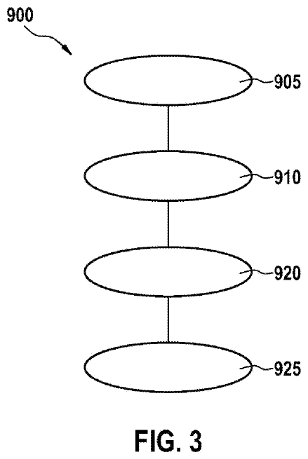

FIG. 3 shows a schematic illustration of a flow chart for a method 900 for operating a controller 150. The method 900 starts with step 905. In step 910, a voltage is determined between a first diagnostic connector 240 and a first protective conductor connector 520. In step 920, a signal S is output if the determined voltage is less than a predetermined lower threshold value or greater than a predetermined upper threshold value. The method ends at step 925.

1. A controller (150) for a charging device (100) for a vehicle (500),
wherein the controller (150) comprises a diagnostic device (200),
wherein the controller (150) is connectable to a V2L device (300) of the vehicle (500) via a first connection line (580),
wherein the controller (150) comprises a first protective conductor connector (520) for connecting to a protective conductor (510) of the vehicle (500),
wherein
the diagnostic device (200) comprises a first diagnostic connector (240) for connecting to the first connection line (580) and comprises a voltage measuring device (230) configured to determine a voltage between the first diagnostic connector (240) and the first protective conductor connector (520),
wherein the diagnostic device (200) diagnoses a fault and outputs a signal (S) if the determined voltage is less than a predetermined lower threshold value or the determined voltage is greater than a predetermined upper threshold value.

2. The controller (150) according to claim 1,
wherein the diagnostic device (200) comprises a current source and/or voltage source (210) connected on the one hand to the first protective conductor connector (520) and to a first resistor (215) on the other hand, wherein the first resistor (215) is connected between the current source and or voltage source (210) and the first diagnostic connector (240).

3. The controller (150) according to claim 2, wherein the first resistor (215) is arranged within the controller (150) or within the charging device (100) or within the V2L device (300).

4. The controller (150) according to claim 1,
wherein the charging device (100) comprises a charging connector for connecting an external power source (600),
wherein, when the external power source is connected to the charging device (100), the protective conductor (510) of the vehicle (500) is connected to a ground cable (610) of the external power source (600).

5. A charging device (100) having a controller (150) according to claim 1.

6. A V2L device (300) for a vehicle (500),
wherein the V2L device comprises a test circuit (400),
wherein the V2L device (300) is connectable to a controller (150) for a charging device (100) of the vehicle (500) via a first connection line (580),
wherein the V2L device (300) comprises a second protective conductor connector (530) for connecting to a protective conductor (510) of the vehicle (500),
wherein
the test circuit (400) comprises a first test connector (450) for connecting to the first connection line (580) and comprises a second resistor (420), wherein the second resistor (420) is connected between the first test connector (450) and the second protective conductor connector (530).

7. The V2L device (300) according to claim 6, wherein the test circuit (400) comprises a first resistor (215) and a second test connector (430), and wherein a series circuit of the first resistor (215) and the second (420) resistor form a voltage divider,
wherein the first resistor (215) is connected to the second test connector (430) on the one hand, and is connected to the second resistor (420) via an intermediate tap (440) on the other hand, and wherein the second resistor (420) is connected to the second protective conductor connector (530) on the one hand, and is connected to the first resistor (215) via the intermediate tap (440) on the other hand, wherein the intermediate tap (440) is connected to the first test connector (450).

8. The V 2L device (300) according to claim 6, wherein the V2L device comprises a socket (460) for connecting a consumer (800), wherein the socket (460) comprises a protective connector (470), wherein the protective connector (470) is connected to the second protective conductor connector (530).

9. A power management system for a vehicle (500), comprising a controller (150) or a charging device (100) having a controller (150) that is configured to be connected to a V2L device (300) of the vehicle (500) via a first connection line (580) and comprises
a diagnostic device (200), and
a first protective conductor connector (520) for connecting to a protective conductor (510) of the vehicle (500),
wherein the diagnostic device (200) comprises a first diagnostic connector (240) for connecting to the first connection line (580) and a voltage measuring device (230) configured to determine a voltage between the first diagnostic connector (240) and the first protective conductor connector (520),
wherein the diagnostic device (200) diagnoses a fault and outputs a signal(S) if the determined voltage is less than a predetermined lower threshold value or the determined voltage is greater than a predetermined upper threshold value; and a V2L device (300) that is configured to be connected to a controller (150) for a charging device (100) of the vehicle (500) via a first connection line (580) and comprises a test circuit (400) and a second protective conductor connector (530) for connecting to a protective conductor (510) of the vehicle (500),
wherein the test circuit (400) comprises a first test connector (450) for connecting to the first connection line (580) and a second resistor (420) wherein the second resistor (420) is connected between the first test connector (450) and the second protective conductor connector (530), according wherein the first diagnostic connector (240) is connected to the first test connector (450) of the V2L device via a first connection line (580).

10. A vehicle (500) having an power management system according to claim 9.

11. A method (900) for operating a controller (150) according to claim 1,
comprising:
determining (910) a voltage between a first diagnostic connector (240) and a first protective conductor connector (520);
outputting (920) a signal(S) if the determined voltage is less than a predetermined lower threshold value or greater than a predetermined upper threshold value.

12. (canceled)

13. A non-transitory, computer-readable storage medium comprising commands which, when executed by a controller (150), cause the controller to
determine (910) a voltage between a first diagnostic connector (240) and a first protective conductor connector (520); and
output (920) a signal (S) if the determined voltage is less than a predetermined lower threshold value or greater than a predetermined upper threshold value.

14. A vehicle (500) having a controller (150) according to claim 1.

15. A vehicle (500) having a charging device according to claim 5.

16. A vehicle (500) having a V2L device according to claim 6.
